(19) United States
(12) Patent Application Publication
(10) Pub. No.: US 2009/0020872 A1
(43) Pub. Date: Jan. 22, 2009

(54) WIRE BONDING METHOD AND SEMICONDUCTOR DEVICE

(75) Inventors: Tatsunari Mii, Tokyo (JP); Hayato Kiuchi, Tokyo (JP)

Correspondence Address: KATTEN MUCHIN ROSENMAN LLP, 575 MADISON AVENUE, NEW YORK, NY, 10022-2585, US

(73) Assignee: SHINKAWA LTD., Tokyo (JP)

(21) Appl. No.: 12/173,048

(22) Filed: Jul. 15, 2008

(30) Foreign Application Priority Data
Jul. 19, 2007 (JP) 2007-187735
Dec. 7, 2007 (JP) 2007-317538

(51) Int. Cl. H01L 23/488; H01L 21/44

(52) U.S. Cl. 257/737; 438/617; 257/E23.024; 257/E21.476

(57) ABSTRACT

In order to prevent bonded wires from being damaged during another wire bonding in a semiconductor device, there is provided a wire bonding method for wire-connecting pads on a semiconductor chip and multiple leads corresponding to the pads in a semiconductor device to be manufactured by sealing the semiconductor chip and the leads together in one block, in which bumps and are formed with an ultrasonic vibration on all of the pads on the semiconductor chip and the leads included in the one block, and then wires are provided, with no ultrasonic vibration, for connection between the bumps and on the pads and the leads.

### BACKGROUND OF THE INVENTION

1. Field of the Invention

The present invention relates to a method of bonding wires in a semiconductor device and to a structure of a semiconductor device.

2. Description of the Related Art

Assembly processes for semiconductor devices such as ICs include a wire bonding step of wire-connecting a semiconductor chip and a lead frame. The wire bonding step typically employs a method of providing wire connections between the semiconductor chip and the lead frame by using a capillary with a wire inserted therethrough, causing discharge from the torch electrode to form a ball at the leading end of the wire protruding outside the capillary, positioning the capillary onto a pad on the semiconductor chip to perform first bonding, and then moving the capillary onto a lead on the lead frame to perform second bonding (refer to Japanese Patent Application Unexamined Publication Disclosure No. H08-340018 for example).

In such a wire bonding method as above, the amount of projection of wires on pad surfaces is so large as to make it impossible to reduce the thickness of the semiconductor device. Hence, there is another method of performing ball bonding as first bonding on leads and stitch bonding as second bonding on pads on a semiconductor chip. However, performing stitch bonding on pads on the semiconductor chip can cause the bonding tool to come into contact with and thereby damage the surface of the semiconductor chip. For this reason, there is still another method for such bonding, in which ball bumps as cushioning media are formed on pads in advance of the bonding and then stitch bonding as second bonding is performed on the ball bumps (refer to Japanese Patent Application Unexamined Publication Disclosure No. H05-326601 for example).

There has also been proposed a method for multi-layer semiconductor devices, in which ball bonding is performed on leads while stitch bonding is performed on pads on the first-layer semiconductor chip with ball bumps formed thereon to connect the leads and pads, and thereafter ball bonding is performed on the bumps on the first-layer semiconductor chip and at suitable positions so as not to come into contact with the wires provided through the preceding stitch bonding while stitch bonding is performed on ball bumps that are formed on pads on the second-layer semiconductor chip to connect the leads and pads on the first- and second-layer semiconductor chips (refer to Japanese Patent No. 3573133 for example). This can prevent the wires that have already been provided between the leads and the first-layer semiconductor chip from being deformed or damaged when providing wire connections between the first- and second-layer semiconductor chips.

Meanwhile, it is becoming more common, in the recent manufacturing of semiconductor devices, to employ a package sealing method in which multiple semiconductor chips are resin-sealed together instead of a separate sealing method in which each semiconductor chip is resin-sealed separately. In the case of employing such a package sealing method, a lead frame is used on which multiple islands for mounting semiconductor chips thereon and multiple leads corresponding thereto are arranged close together in one block, with tapes for prevention of leakage of sealant applied on the reverse side thereof. In the case of fixing such a lead frame onto a bonding stage for bonding, the lead frame is to be brought into vacuum contact with the bonding stage via the tapes on the reverse side, and to be pressed from above at the periphery of each block with multiple semiconductor chips in close arrangement. This causes the lead frame to be fixed poorly onto the bonding stage, resulting in a problem of wire vibration during wire bonding.

For example, there has been a problem in that applying an ultrasonic vibration to a wire during wire bonding can cause a crack in a portion where another wire that has already been subject to bonding is bonded to a lead or in a ball neck on a pad, which could lead to disconnection. Even in the case a wire to be bonded is not particularly adjacent to another wire that has already been bonded, the bonded wire can vibrate to be damaged or to damage the ball neck, resulting in a problem of potential disconnection.

However, the patent documents cited above include no description of the case where a non-adjacent bonded wire can be damaged during such bonding, and the related arts described in the patent documents cannot solve these problems.

### SUMMARY OF THE INVENTION

It is an object of the present invention to prevent bonded wires from being damaged during another bonding.

The present invention is directed to a wire bonding method including: a first bump forming step of forming first bumps on all pads in a block of at least one semiconductor chip; a second bump forming step of forming second bumps on all leads in the block, each of the leads corresponding to one of the pads; and a wire connecting step of providing wire connections between the bumps and the leads after the two bump forming steps, with no ultrasonic vibration.

In the wire bonding method, the wire connecting step may be performed after the first and second bump forming steps. The wire bonding method may also include a sealing step of the block during the first and second bump forming steps and the wire connecting step. In the wire bonding method, the sealing step may include fixing an outer frame of the block using a presser frame. The wire bonding method may also include: moving the presser frame and fixing a further outer frame of a further block of at least one further semiconductor chip; and repeating the two bump forming steps and the wire connecting step on the further block. The wire bonding method may also include removing the presser frame; and cutting the block to isolate the at least one semiconductor device and the at least one further semiconductor device.

The wire connecting step of the wire bonding method may also include: a first bonding step of bonding a wire to at least one of the first and second bumps with no ultrasonic vibration; a looping step of looping the wire from the at least one of the first and second bumps toward at least one other of the first and second bumps, the at least one other of the first and second bumps being for the pad or lead corresponding to the at least one of the first and second bumps; and a second bonding step of bonding the looped wire to the other of the first and second bumps with no ultrasonic vibration. In the wire bonding method, the first bonding step is a ball bonding step of bonding an initial ball formed at the leading end of the wire to one bump on the pads or the leads with no ultrasonic vibration, the wire being inserted through a capillary and protruding from the lower end thereof. The wire bonding method may also include: a ball bonding step of bonding an initial ball formed at the leading end of the wire to one bump on the pads or the leads with no ultrasonic vibration, the wire being inserted through a capillary and protruding from the lower end thereof; and a pressing portion forming step of squashing a ball neck formed through the ball bonding step with the capillary and of pressing the side surface of the wire folded back on the squashed ball neck to form a pressing portion. In the wire bonding method, the looping step may include looping the wire from the pressing portion toward the leads or the pads. In the wire bonding method, the first and second bump forming steps may involve applying no ultrasonic vibration to form bumps.

A semiconductor device is provided that includes: first bumps formed on a plurality of pads on at least one semiconductor chip in a block; second bumps formed on a plurality of leads on the at least one semiconductor chip, each of the leads corresponding to a respective pad; and wires provided for connection between the bumps. In the semiconductor device, first and second bumps and the wires are formed on the at least one semiconductor chip together in one block, and no ultrasonic vibration is applied to the block after the first and second bumps are formed on all of the pads and the leads on the at least one semiconductor chip included in the block.

In the semiconductor device, each of the wires may be bonded to one of a first and second bump, looped from the one of the first and second bumps toward one other of the first and second bumps, the one other of the first and second bumps being for the pad or lead corresponding to the one of the first and second bumps, and bonded to the other of the first and second bumps. In the semiconductor device, the first and second bumps may be formed with no ultrasonic vibration.

The present invention exhibits an advantageous effect of preventing bonded wires from being damaged during another bonding.

### BRIEF DESCRIPTION OF THE SEVERAL VIEWS OF THE DRAWINGS

FIG. 1 is a plan view of a lead frame for use in manufacturing a semiconductor device according to an embodiment of the present invention;

FIG. 2 is a cross-sectional view showing a state where the lead frame for the semiconductor device according to the embodiment of the present invention is fixed on a bonding stage;

FIG. 3 is a partial plan view showing a state where bumps are formed and wires are bonded on the lead frame for the semiconductor device according to the embodiment of the present invention;

FIG. 4 is an illustrative view of a connection between a semiconductor chip and a lead in the semiconductor device according to the embodiment of the present invention;

FIG. 5 is a perspective view of portions where bumps formed on a pad and a lead and a wire are bonded in the semiconductor device according to the embodiment of the present invention;

FIG. 6 is an illustrative view of a bonding step for the semiconductor device according to the embodiment of the present invention;

FIG. 7 is an illustrative view of bump formation in the bonding step for the semiconductor device according to the embodiment of the present invention;

FIG. 8 is an illustrative view of bump formation in the bonding step for the semiconductor device according to the embodiment of the present invention;

FIG. 9 is an illustrative view of bump formation in the bonding step for the semiconductor device according to the embodiment of the present invention;

FIG. 10 is an illustrative view of ball bonding in the bonding step for the semiconductor device according to the embodiment of the present invention;

FIG. 11 is an illustrative view of ball bonding in the bonding step for the semiconductor device according to the embodiment of the present invention;

FIG. 12 is an illustrative view of looping in the bonding step for the semiconductor device according to the embodiment of the present invention;

FIG. 13 is an illustrative view of looping in the bonding step for the semiconductor device according to the embodiment of the present invention;

FIG. 14 is an illustrative view of stitch bonding in the bonding step for the semiconductor device according to the embodiment of the present invention;

FIG. 15 is an illustrative view of a connection between a semiconductor chip and a lead in a semiconductor device according to another embodiment of the present invention;

FIG. 16 is a perspective view of a portion where a bump formed on a pad and a wire are bonded in the semiconductor device according to another embodiment of the present invention; and

FIG. 17 is an illustrative view of a bonding step of forming a pressing portion in the semiconductor device according to another embodiment of the present invention.

### DETAILED DESCRIPTION OF THE INVENTION

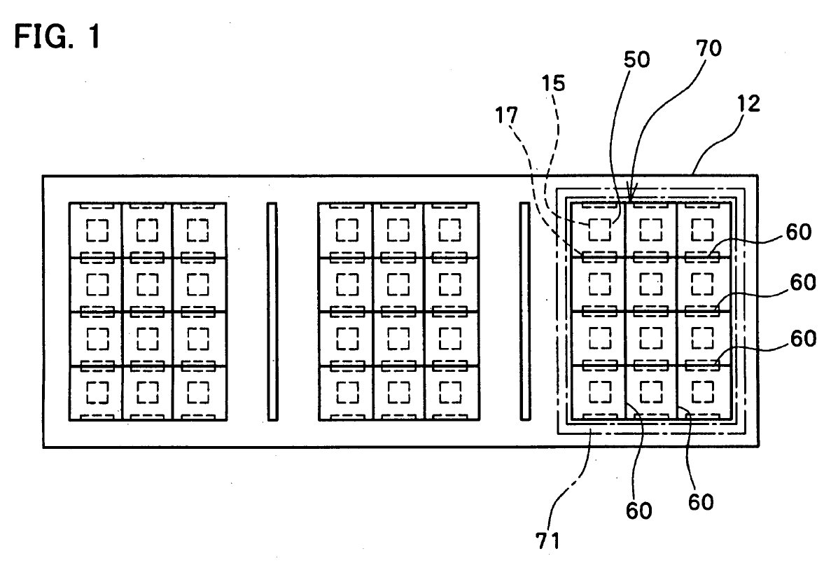

Embodiments of a wire bonding method and a semiconductor device according to the present invention will hereinafter be described with reference to the accompanying drawings. As shown in FIG. 1, a lead frame 12 for use in manufacturing semiconductor devices by a resin package sealing method is provided with a plurality set of islands 15 for mounting semiconductor chips thereon and leads 17 corresponding to pads on the semiconductor chips to be mounted on the islands 15. One pair of each island 15 and lead corresponding thereto constitutes one segment 50. Each segment 50 is to be one semiconductor device by cutting off at cut-off regions 60 provided therebetween after mounting of a semiconductor chip, wire bonding, and resin sealing. A plurality of such segments 50 are provided close together on the lead frame 12 to constitute one block 70. Each block 70 is a package area for resin sealing. Each block 70 also has a space therearound, so that the outer periphery of each block can be pressed and fixed from above with a presser frame 71 during wire bonding.

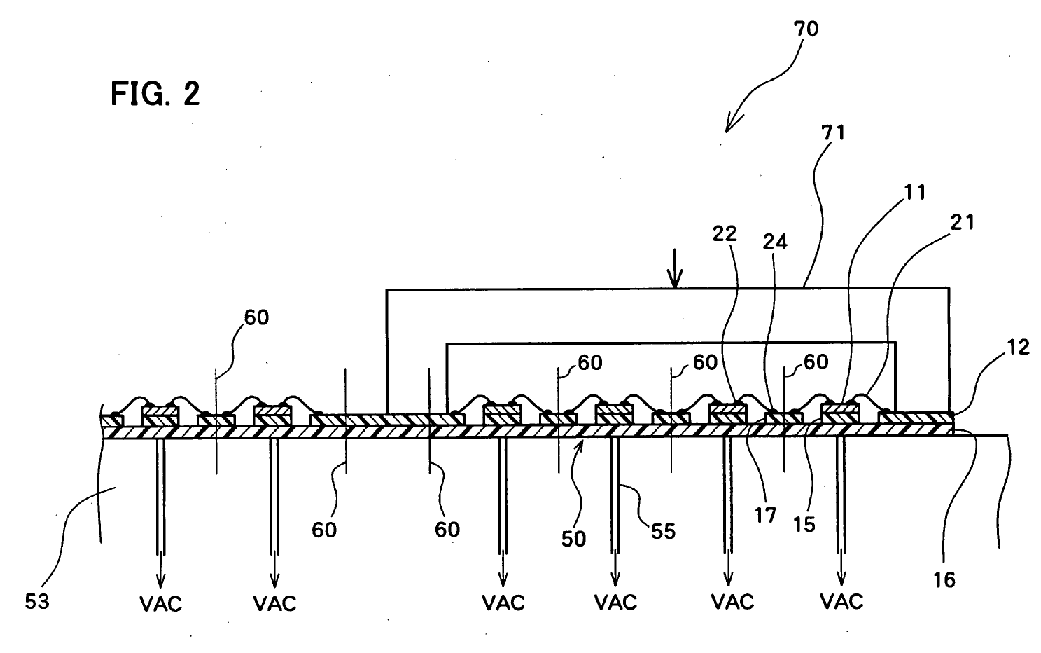

As shown in FIG. 2, on the reverse side of the lead frame 12 is applied a peelable tape 16 to prevent leakage of sealing resin from between the islands 15 and the leads 17. After semiconductor chips 11 are mounted on the islands 15, the thus arranged lead frame 12 is carried onto a bonding stage 53 and, by vacuum contact pores 55 in the bonding stage 53, brought into vacuum contact with the bonding stage 53 via the tape 16, and further is pressed from above by the presser frame 71 at the periphery of each block 70 to be fixed to the bonding stage 53. Then, after bumps 22 and 24 are formed on pads 13 on the semiconductor chips 11 and the leads 17, wires 21 are provided for connection between the bumps 22 and 24.

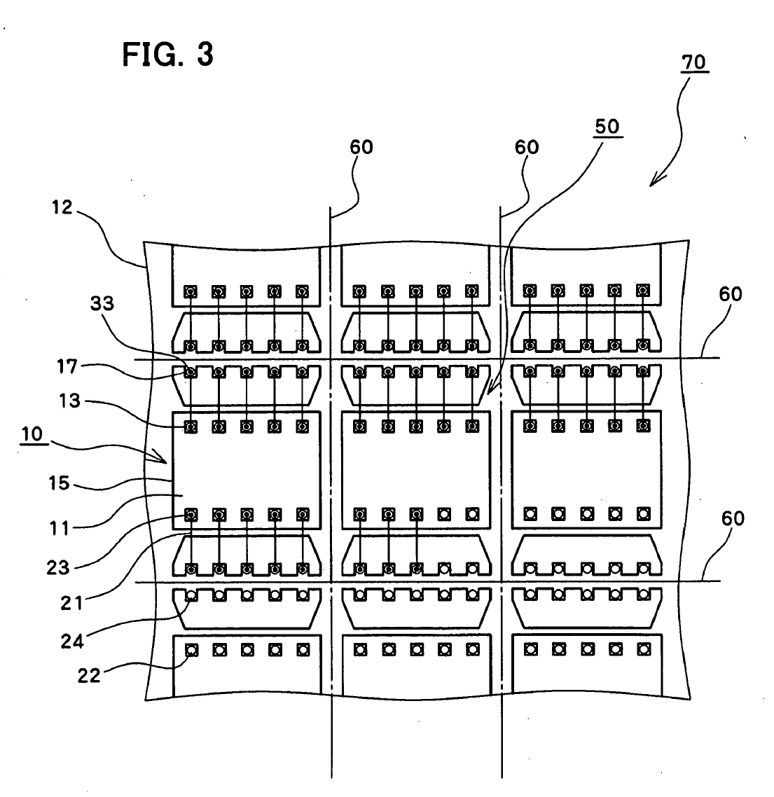

After the lead frame 12 is fixed onto the bonding stage 53, gold bumps 22 and 24 are formed, by pressure bonding with an ultrasonic vibration, on the pads 13 on the semiconductor chips 11, which are mounted on the islands 15, and the leads 17, as shown in FIG. 3. Then, after gold bumps 22 and 24 are formed on all of the pads 13 and leads 17 included in the block 70, wires 21 are provided sequentially, only by pressure bonding with no ultrasonic vibration, for connection between the bumps 22 and 24 on the pads 13 on the semiconductor chips 11, which are mounted on the islands 15, and the corresponding leads 17. Then, after the wires 21 are provided for connection between the bumps 22 and 24 on all of the pads 13 and the corresponding leads 17 included in the block 70, the vacuum of the bonding stage 53 is released and the presser frame 71 is brought up to move the lead frame 12, so that the next block 70 comes over the bonding stage 53. Thus, wires 21 are to be bonded sequentially between pads 13 and leads 17 included in each block 70. Then, after the connections between all of the pads 13 on the semiconductor chips 11 and the corresponding leads 17 on the lead frame 12 are completed, the lead frame 12 is resin-sealed by each block 70, and thereafter cut off at the cut-off regions 60 to be semiconductor devices 10.

In such semiconductor devices, external connection electrodes do not protrude from the resin-sealed package but are formed on the reverse side of the package, called QFN (Quad Flat Non-leaded Package).

In the present embodiment, ultrasonic vibration is applied only when the pads 13 and leads 17 included in each block 70 are independent of each other without being connected through wires 21. That is, no ultrasonic vibration is applied when connecting wires 21 at positions adjacent to bonded wires 21 to connect wires 21 only by pressure bonding. This exhibits an advantageous effect of preventing bonded wires 21 from being damaged during another bonding in the same block 70.

In addition, since spaces are provided between the blocks 70 as shown in FIG. 1 and the periphery of each block 70 is pressed by the presser frame 71 during bonding, vibrations due to an ultrasonic vibration applied when forming bumps 22 and 24 in one block 70 cannot be transmitted to connected wires 21 included in adjacent blocks 70. This exhibits an advantageous effect of preventing bonded wires 21 in one block 70 from being damaged during additional bonding in another block 70.

Although the foregoing description of the present embodiment is based on the assumption that one block 70 includes multiple semiconductor chips 11 and multiple leads, only one semiconductor chip can be included in one block 70. Although the foregoing description of the present embodiment is also based on the assumption that after gold bumps 22 and 24 are formed by pressure bonding with an ultrasonic vibration, wires 21 are provided sequentially, only by pressure bonding with no ultrasonic vibration, for connection between the bumps 22 and 24 on the pads 13 and the corresponding leads 17, heat can be applied when forming bumps and/or connecting wires. In this case, after gold bumps 22 and 24 are formed by heating and pressure bonding with an ultrasonic vibration, wires 21 are provided sequentially, only by heating and pressure bonding with no ultrasonic vibration, for connection between the bumps 22 and 24 on the pads 13 and the corresponding leads 17.

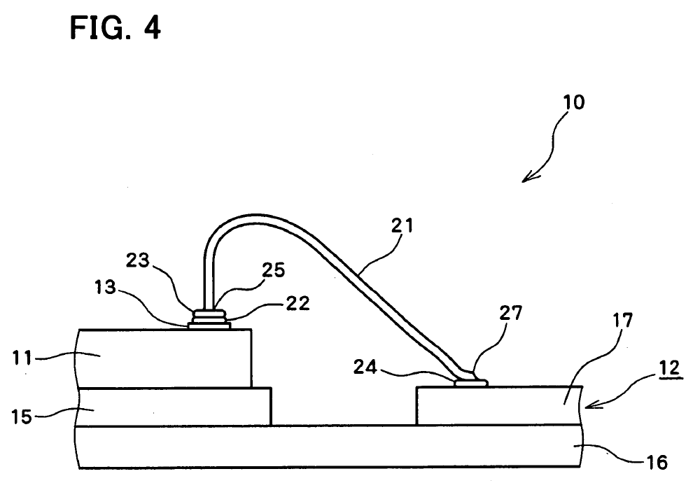

Wire bonding will hereinafter be described in detail. As shown in FIG. 4, the semiconductor device 10 includes: a bump 22 formed on a pad 13 on a semiconductor chip 11 that is mounted on an island 15 of a lead frame 12 with a tape 16 applied on the reverse side thereof; a bump 24 formed on a lead 17 of the lead frame 12; and a wire 21 for connecting the bumps 22 and 24. The wire 21 includes: a crimping ball 23 ball-bonded onto the bump 22 formed on the pad 13 on the semiconductor chip 11; a ball neck 25, the cross-sectional area thereof decreasing from the crimping ball 23 toward the wire 21; a looped portion rising in the direction of the thickness of the semiconductor chip 11 from the ball neck 25 toward the lead 17; and a stitch bonding portion 27 bonded to the bump 24 on the lead 17.

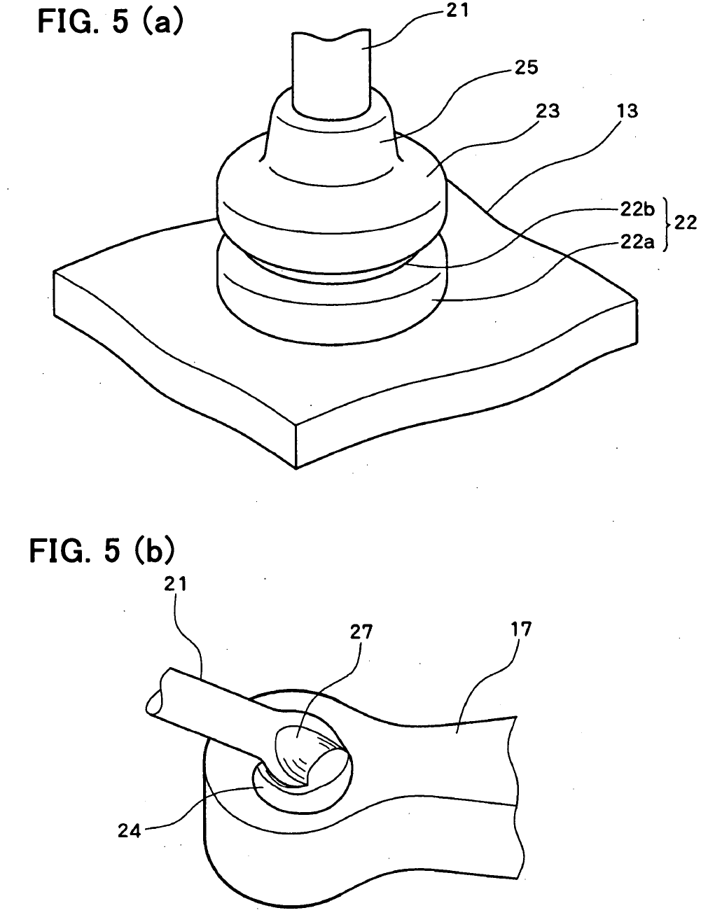

As shown in FIG. 5(a), on the pad 13 are bonded a thick disk-shaped bump base portion 22a, a bump wire 22b disposed on the bump base portion 22a and having a diameter slightly smaller than that of the bump base portion 22a, and crimping ball 23 disposed on the bump wire 22b and having a diameter approximately the same as that of the bump base portion 22a, in a stacked manner in this order. The ball neck 25, which is slightly thicker than the wire 21 and has a columnar shape, is formed on the upper surface of the crimping ball 23, the ball neck 25 continuing to the wire 21.

As shown in FIG. 5(b), the bump 24 formed on the lead 17 has a similar shape as the bump 22 formed on the pad 13, and the end portion of the stitch bonding portion 27 of the wire 21 bonded onto the bump 24 has a slant face following the shape of the capillary.

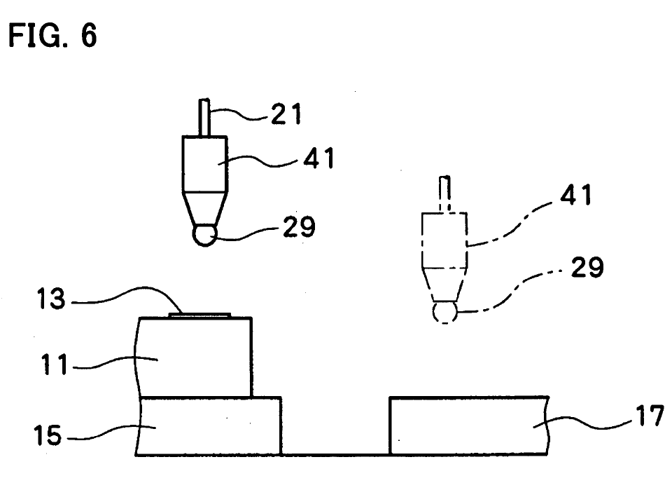

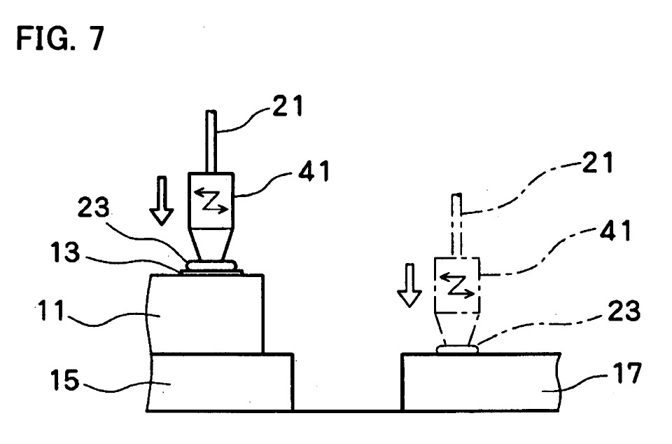

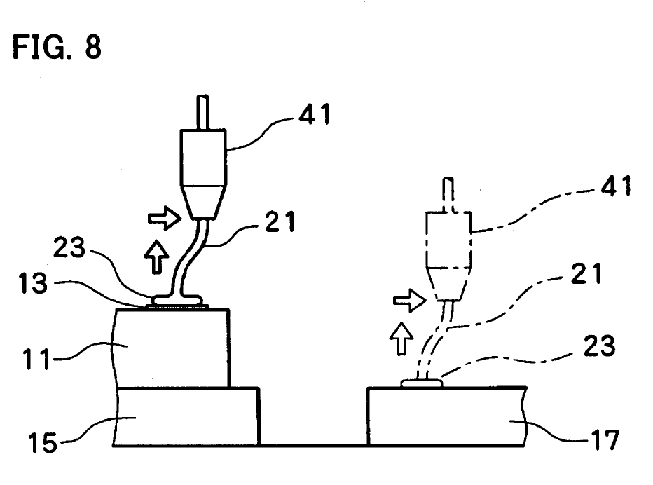

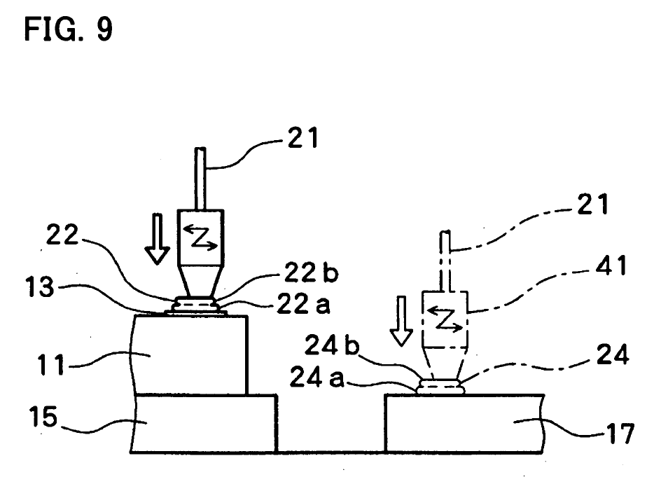

A bonding process will now be described with reference to FIGS. 6 to 14. A bump forming step will first be described with reference to FIGS. 6 to 9. As shown in FIG. 6, an initial ball 29 is formed at the leading end of a gold wire 21 inserted through a capillary 41. Then, as shown in FIG. 7, the initial ball 29 formed at the leading end of the wire 21 is pressed and bonded onto the pad 13 with an ultrasonic vibration by the capillary 41. This causes a gold crimping ball 23 to be formed on the pad 13. After the formation of the crimping ball 23, the capillary 41 is brought up and moved laterally while reeling out the wire 21, as shown in FIG. 8. Although the capillary 41 is moved laterally from the pad 13 toward the lead 17 in the present embodiment, the direction of the lateral movement is not restricted thereto. Then, as shown in FIG. 9, the capillary 41 is brought down, and when the gold wire 21 reeled out over the crimping ball 23 is pressed onto the crimping ball 23, the crimping ball 23 is compressed to be a gold bump base portion 22a, while the wire 21 is deformed to be a gold bump wire 22b. The bump base portion 22a and the bump wire 22b constitute a gold bump 22. After this the capillary 41 is brought up while reeling out the wire 21 at the leading end thereof, and then the wire 21 is cut by closing a clamper not shown in the drawings to complete the bump forming step. After the bump forming step on the pad 13, the capillary 41 is moved over the lead 17 to form a gold bump 24 on the lead 17 in the same manner as the bump forming step on the pad 13, as shown by the alternate long and short dash lines of FIGS. 6 to 9. As described heretofore, the bump forming step forms a bump by pressure-bonding the wire 21 with an ultrasonic vibration.

The bump forming step above is repeated on all of the pads 13 and leads 17 included in the block 70 as a package for resin sealing shown in FIGS. 1 to 3.

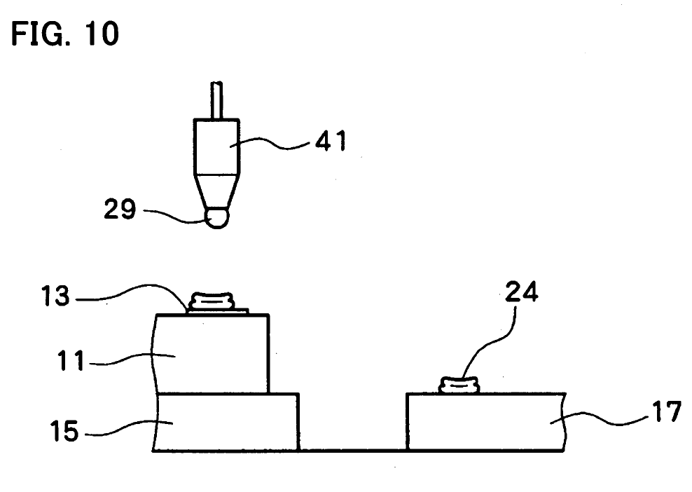

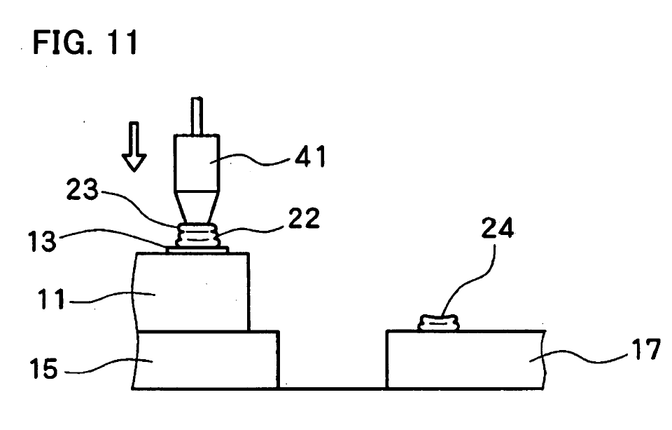

After bumps 22 and 24 are formed on all of the pads 13 and leads 17 included in the block 70 as a package for resin sealing shown in FIGS. 1 to 3, a first bonding step is performed as shown in FIGS. 10 and 11. As shown in FIG. 10, an initial ball 29 is formed at the leading end of a gold wire 21 inserted through the capillary 41. Then, as shown in FIG. 11, the capillary 41 is brought down and the initial ball 29 is pressed onto the bump 22 with no ultrasonic vibration. The bump 22 is formed from the gold wire 21 to be naturally of gold. The initial ball 29 is also formed from the gold wire to be naturally of gold. Consequently, the pressure bonding between the initial ball 29 and the bump 22 is achieved by two gold members easy to bond, which allows a strength required for the bonding to be ensured only by pressure bonding with no ultrasonic vibration.

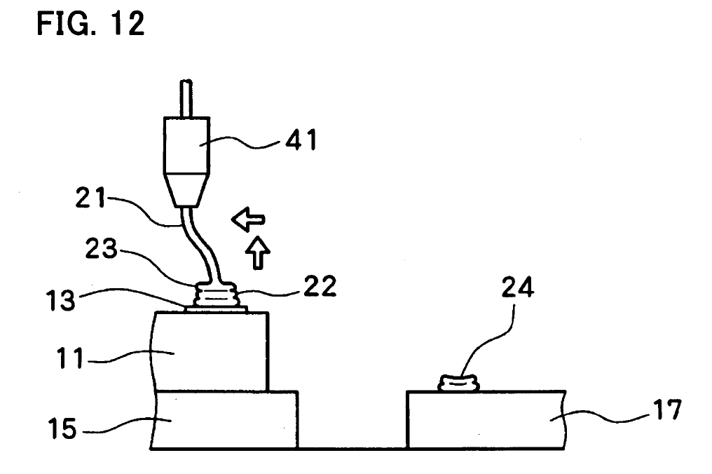

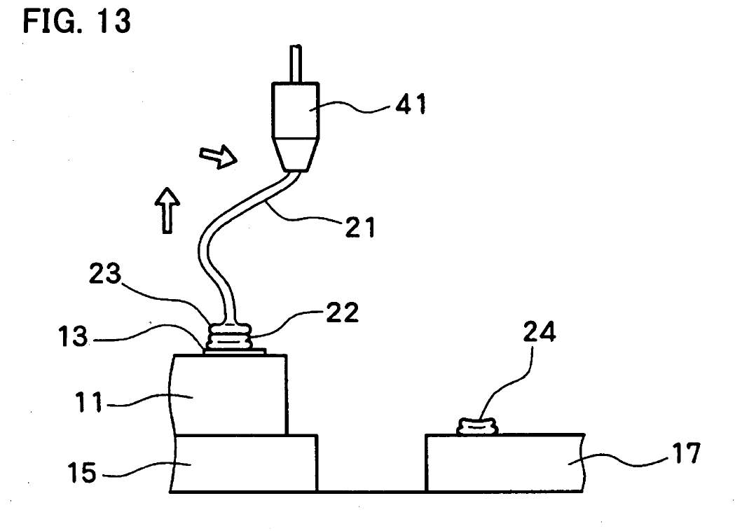

After the initial ball 29 is bonded to the bump 22, a looping step is performed. As shown in FIG. 12, the capillary 41 is brought up while reeling out the gold wire 21 at the leading end thereof and is moved laterally in the opposite direction of the lead 17. Then, as shown in FIG. 13, the capillary 41 is moved toward the lead 17 while further reeling out the wire 21.

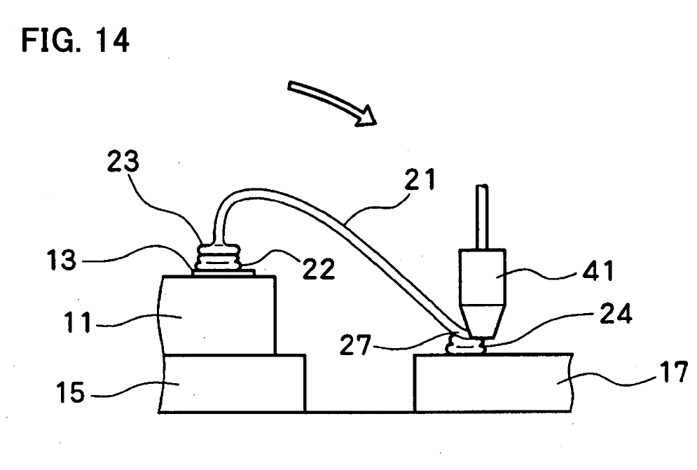

As shown in FIG. 14, after the looping step, the capillary 41 is brought down onto the bump 24 on the lead 17 to perform a second bonding step in which the wire 21 is pressed against the bump 24 with no ultrasonic vibration. Since the bump 24 is also formed from the gold wire 21 to be naturally of gold, the pressure bonding between the wire 21 and the bump 24 is achieved by two gold members easy to bond, which allows a strength required for the bonding to be ensured only by pressure bonding with no ultrasonic vibration. Thus pressing the wire 21 against the bump 24 causes a stitch bonding portion 27 to be formed with the end face thereof following the shape of the capillary 41.

After the first bonding step, looping step, and second bonding step above are repeated between the bumps 22 and 24 on all of the pads 13 and the corresponding leads 17 included in the block 70 shown in FIGS. 1 to 3, so that the bumps 22 and 24 are connected only by pressure bonding with no ultrasonic vibration, the vacuum of the bonding stage 53 shown in FIG. 2 is released and the presser frame 71 is brought up to move the lead frame 12, so that the next block 70 comes over the bonding stage 53. Thus, wires 21 are to be bonded sequentially between the bumps 22 and 24 on pads 13 and leads 17 included in each block 70.

As described heretofore, in the present embodiment, gold bumps 22 and 24 are formed on all pads 13 and leads 17 included in one block 70 with an ultrasonic vibration only when the pads 13 and leads 17 are independent of each other without being connected through wires 21, and then gold wires 21 are provided, only by pressure bonding with no ultrasonic vibration, for connection between the bumps 22 and 24 on the pads 13 and leads 17, whereby no ultrasonic vibration can be applied when connecting wires 21 at positions adjacent to bonded wires 21.

This exhibits an advantageous effect of preventing bonded wires 21 in the same block 70 from being damaged by vibrations due to an ultrasonic vibration, that is, of preventing bonded wires 21 from being damaged during another bonding.

Although the foregoing description of the present embodiment is based on the assumption that the bumps 22 on the pads 13 undergo ball bonding and the bumps 24 on the leads 17 undergo stitch bonding, wires can be ball-bonded onto the bumps 24 on the leads 17 and then looped over the pads 13 to be stitch-bonded onto the bumps 22 on the pads 13. Although the foregoing description of the present embodiment is also based on the assumption that after gold bumps 22 and 24 are formed by pressure bonding with an ultrasonic vibration, wires 21 are provided sequentially, only by pressure bonding with no ultrasonic vibration, for connection between the bumps 22 and 24 on the pads 13 and the corresponding leads 17, heat can be applied when forming bumps and/or connecting wires. In this case, after gold bumps 22 and 24 are formed by heating and pressure bonding with an ultrasonic vibration, wires 21 are provided sequentially, only by heating and pressure bonding with no ultrasonic vibration, for connection between the bumps 22 and 24 on the pads 13 and the corresponding leads 17.

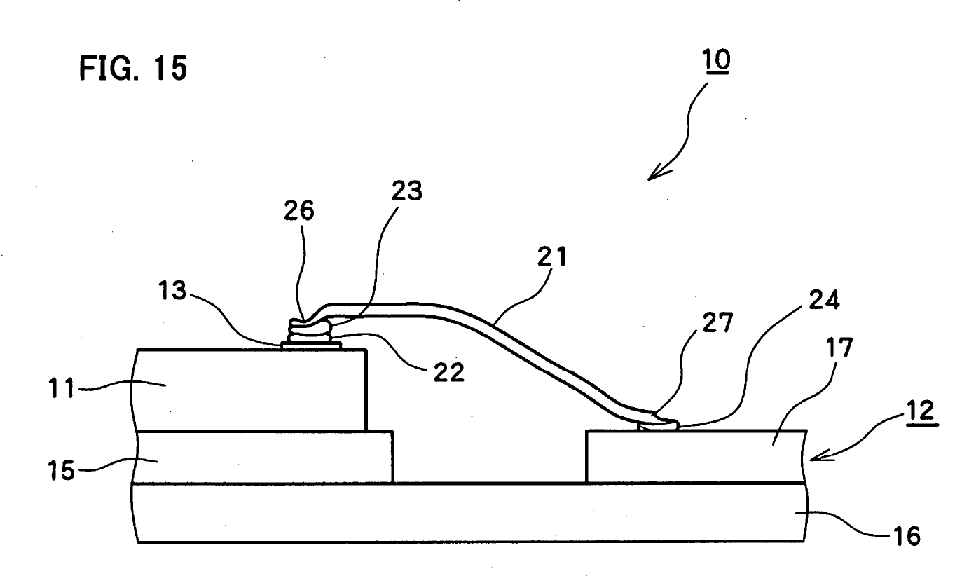

Another embodiment will now be described with reference to FIGS. 15 to 17. It is noted that components identical with those in the above-described embodiment are designated by the same reference numerals to omit descriptions thereof. As shown in FIG. 15, the semiconductor device 10 includes: a bump 22 formed on a pad 13 on a semiconductor chip 11 that is mounted on an island 15 of a lead frame 12 with a tape 16 applied on the reverse side thereof; a bump 24 formed on a lead 17 of the lead frame 12; and a wire 21 for connecting the bumps 22 and 24. The wire 21 includes: a crimping ball 23 bonded onto the pad 13 on the semiconductor chip 11; a pressing portion 26 formed by squashing such a ball neck 25 as shown in FIG. 4 or 5 and pressing the side surface of the wire 21 folded back on the squashed ball neck 25; a looped portion extending from the pressing portion 26 toward the lead 17; and a stitch bonding portion 27 bonded to the bump 24 on the lead 17.

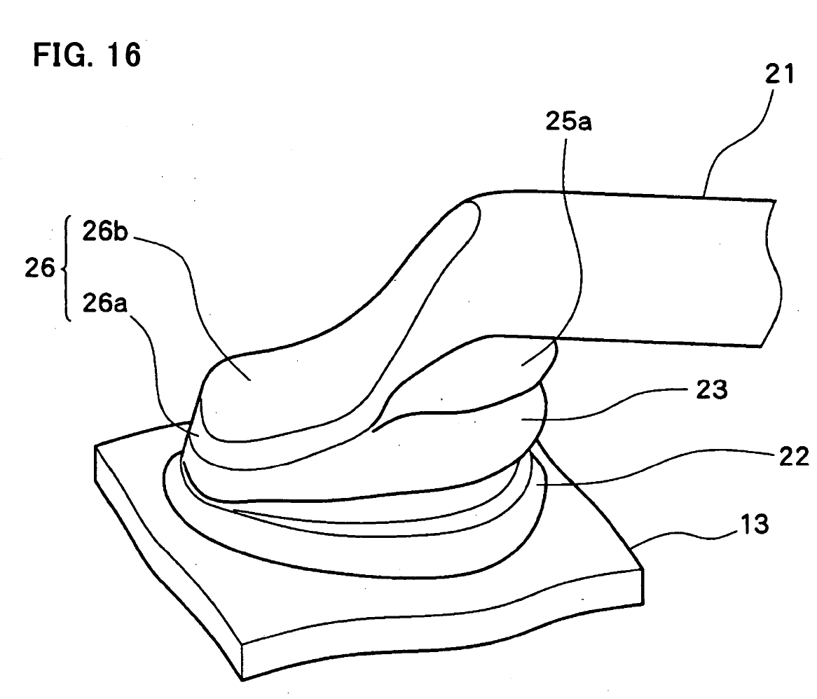

As shown in FIG. 16, the pressing portion 26 formed on the pad 13 on the semiconductor chip 11 includes: a squashed portion 25a formed by squashing the ball neck 25 shown in FIG. 4 or 5 on the crimping ball 23 on the pad 13 to have a flat upper surface; a fold-back portion 26a formed by folding back the wire 21 convexly in the opposite direction of the lead 17 with respect to the squashed portion 25a; and a flat portion 26b formed by pressing the side surface of the wire 21 continuing to the fold-back portion 26a toward the squashed portion 25a to have a flat upper surface that follows the shape of the capillary. The surface of the flat portion 26b on the pad 13 side is pressed against the upper surface of the squashed portion 25a. Also, the arrangement of the portion where the wire 21 and the bump 24 on the lead 17 are bonded is the same as in the embodiment described above with reference to FIG. 5(b).

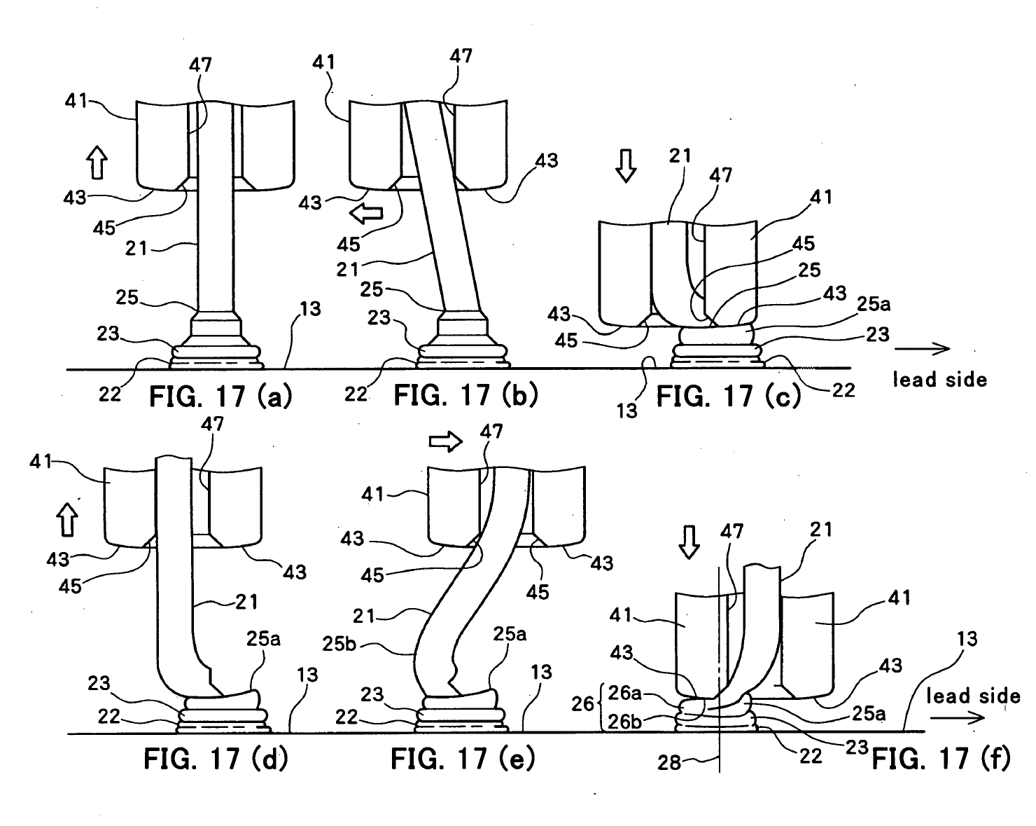

A bonding method according to the present embodiment will hereinafter be described with reference to FIG. 17. The bump forming step of forming bumps 22 and 24 on pads 13 and leads 17 is the same as in the embodiment described above with reference to FIGS. 6 to 9, and the descriptions thereof will be omitted.

As is the case with the above-described embodiment, a first bonding step is performed in which an initial ball (not shown in the drawing) formed at the leading end of the wire 21 is pressed and bonded onto the bump 22 formed on the pad 13 with no ultrasonic vibration by the capillary 41, and a crimping ball 23 and a ball neck 25 are formed on the bump 22 on the pad 13.

After the first bonding step, a pressing portion forming step is performed in which a pressing portion 26 is formed only by pressing pressure with no ultrasonic vibration as shown in FIGS. 17(a) to 17(f). It is noted that leads 17 exist on the right side in each of FIGS. 17(a) to 17(f), though no lead 17 is shown in the drawings. In the pressing portion forming step, the wire 21 is reeled out and the capillary 41 is brought up as shown in FIG. 17(a), and then the capillary 41 is moved in the opposite direction of the lead 17 until a face portion 43 of the capillary 41 on the lead 17 side comes over the ball neck 25 as shown in FIG. 17(b). In this case, the wire 21 is tilted in the opposite direction of the lead 17 with respect to the ball neck 25. Then, as shown in FIG. 17(c), the capillary 41 is brought down to cause the face portion 43 of the capillary 41 to squash the ball neck 25 and thereby to form a squashed portion 25a on the crimping ball 23. The squashed portion 25a is squashed by the face portion 43 of the capillary 41 to have a flat upper surface that follows the shape of the face portion 43. Also, the wire 21 is bent in the opposite direction of the lead 17 with respect to the squashed portion 25a and extends perpendicular to the pad 13 along the inner surface of a straight hole 47 in the capillary 41 on the opposite side of the lead 17.

Then, as shown in FIG. 17(d), the wire 21 is reeled out and the capillary 41 is brought up again, so that the wire 21 is reeled out in a straight manner along the straight hole 47 in the capillary 41. Then, as shown in FIG. 17(e), the capillary 41 is moved toward the lead 17 to thereby cause the wire 21 to be pressed toward the lead 17 by an inner chamfer portion 45 of the capillary 41 and to be bent at a bent portion 25b that continues from the squashed portion 25a. Then, the capillary 41 is moved toward the lead 17 until the face portion 43 of the capillary 41 on the opposite side of the lead 17 comes over the crimping ball 23. Then, as shown in FIG. 17(f), the capillary 41 is brought down to cause the side surface of the wire 21 to be pressed against the squashed portion 25a, which is formed by squashing the ball neck 25. Thus pressing the wire 21 causes the bent portion of the wire 21 to be folded back toward the squashed portion 25a and thereby the fold-back portion 26a to be formed. The pad 13 side of the pressing portion 26 of the wire 21 is pressed against the upper surface of the squashed portion 25a, while the upper surface of the pressing portion 26 is made flat by the face portion 43 of the capillary 41. When the pressing portion forming step is completed, the capillary 41 is positioned nearer the lead 17 with respect to the bonding center line 28 of the pad 13.

The pressing portion 26 is formed by the above-described bonding method, in which the wire 21 is folded back and pressed against the surface of the bump 22 formed on the pad 13. The lower surface of the pressing portion 26 is pressed against the squashed portion 25a formed on the crimping ball 23.

In addition to the same advantageous effect as in the above-described embodiment, the present embodiment exhibits an advantageous effect that the thickness of the semiconductor device 10 can be smaller than in the above-described embodiment, because the amount of projection of wires on the pads 13 is small even if wire bonding can be performed from the pads 13 on the semiconductor chip 11 toward the leads 17.

The present embodiment, the foregoing description of which is based on the assumption that bonding is performed from pads 13 toward leads 17, can also be applied to the case of bonding from leads 17 toward pads 13. Further, in the present embodiment, heat can be applied when forming bumps and/or connecting wires, as is the case in the above-described embodiment. In this case, after gold bumps 22 and 24 are formed by heating and pressure bonding with an ultrasonic vibration, wires 21 are provided sequentially, only by heating and pressure bonding with no ultrasonic vibration, for connection between the bumps 22 and 24 on the pads 13 and the corresponding leads 17.

Although the foregoing descriptions of the embodiments are based on the assumption that gold bumps 22 and 24 are formed on pads 13 and leads 17 by pressure bonding with an ultrasonic vibration or by heating and pressure bonding with an ultrasonic vibration, the bumps 22 and 24 can be formed only by pressure bonding or only by heating and pressure bonding with no ultrasonic vibration depending on the metallic materials for use in forming pads 13 and leads 17. In addition to the same advantageous effect as in the above-described embodiments, this case exhibits an advantageous effect that the lead frame 12 is less likely to be damaged even if fixed poorly, because vibrations due to an ultrasonic vibration cannot be transmitted to the lead frame 12.

What is claimed is:

1. A wire bonding method, comprising:
a first bump forming step of forming first bumps on all pads in a block of at least one semiconductor chip;
a second bump forming step of forming second bumps on all leads in the block, each of the leads corresponding to one of the pads; and
a wire connecting step of providing wire connections between the bumps and the leads, with no ultrasonic vibration.

2. The wire bonding method according to claim 1, wherein the wire connecting step is performed after the first and second bump forming steps.

3. The wire bonding method according to claim 1, further comprising a sealing step of the block during the first and second bump forming steps and the wire connecting step.

4. The wire bonding method according to claim 1, wherein the sealing step further comprises fixing an outer frame of the block using a presser frame.

5. The wire bonding method according to claim 4, further comprising:
moving the presser frame and fixing a further outer frame of a further block of at least one further semiconductor chip; and
repeating the two bump forming steps and the wire connecting step on the further block.

6. The wire bonding method according to claim 5, further comprising:
removing the presser frame; and
cutting the block to isolate the at least one semiconductor device and the at least one further semiconductor device.

7. The wire bonding method according to claim 1, the wire connecting step further comprising:
a first bonding step of bonding a wire to at least one of the first and second bumps with no ultrasonic vibration;
a looping step of looping the wire from the at least one of the first and second bumps toward at least one other of the first and second bumps, the at least one other of the first and second bumps being for the pad or lead corresponding to the at least one of the first and second bumps; and
a second bonding step of bonding the looped wire to the other of the first and second bumps with no ultrasonic vibration.

8. The wire bonding method according to claim 7, wherein
the first bonding step is a ball bonding step of bonding an initial ball formed at the leading end of the wire to one bump on the pads or the leads with no ultrasonic vibration, the wire being inserted through a capillary and protruding from the lower end thereof.

9. The wire bonding method according to claim 7, the first bonding step further comprises:
a ball bonding step of bonding an initial ball formed at the leading end of the wire to one bump on the pads or the leads with no ultrasonic vibration, the wire being inserted through a capillary and protruding from the lower end thereof; and
a pressing portion forming step of squashing a ball neck formed through the ball bonding step with the capillary and of pressing the side surface of the wire folded back on the squashed ball neck to form a pressing portion, and wherein
the looping step is looping the wire from the pressing portion toward the leads or the pads.

10. The wire bonding method according to claim 1, wherein the first and second bump forming steps apply no ultrasonic vibration to form bumps.

11. A semiconductor device, comprising:
first bumps formed on a plurality of pads on at least one semiconductor chip in a block;
second bumps formed on a plurality of leads on the at least one semiconductor chip, each of the leads corresponding to a respective pad and being in the block; and
wires provided for connection between the first and second bumps without ultrasonic vibration being applied to the block after the first and second bumps are formed.

12. The semiconductor device according to claim 11, wherein
each of the wires is bonded to one of a first and second bump, looped from the one of the first and second bumps toward one other of the first and second bumps, the one other of the first and second bumps being for the pad or lead corresponding to the one of the first and second bumps, and bonded to the other of the first and second bumps.

13. The semiconductor device according to claim 12, wherein
the first and second bumps are formed with no ultrasonic vibration.

14. The semiconductor device according to claim 11, wherein
the first and second bumps are formed with no ultrasonic vibration.
